(19) United States
(12) Patent Application Publication
(10) Pub. No.: US 2009/0218696 A1
(43) Pub. Date: Sep. 3, 2009

(54) SEMICONDUCTOR DEVICE INCLUDING A PADDING UNIT

(75) Inventors: Sun-Hwa JUNG, Icheon-si (KR); Wan-Cheul Shin, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/395,499

(22) Filed: Feb. 27, 2009

(30) Foreign Application Priority Data
Feb. 28, 2008 (KR) 10-2008-0018200
Nov. 17, 2008 (KR) 10-2008-0113982

(51) Int. Cl. H01L 23/52

(52) U.S. Cl. 257/762; 257/773; 257/E23.141

(57) ABSTRACT

A semiconductor device includes bit lines formed over a substrate and a padding unit formed over the bit lines. The padding unit includes stacked padding layers. A lower padding layer is formed between the bit lines and an upper padding layer. The upper layer as a slit formed therein. The lower padding layer prevents damage to the bit lines due to plasma gas entering through the slit.

### CROSS-REFERENCE TO RELATED APPLICATIONS

The present invention claims priority of Korean patent application numbers 10-2008-0018200 and 10-2008-0113982, filed on Feb. 28, 2008, and Nov. 17, 2008, respectively, which are incorporated by reference in their entirety.

### BACKGROUND OF THE INVENTION

The present invention relates to a semiconductor device, and more particularly, to a semiconductor device including a padding unit which comprises two or more padding layers.

A semiconductor device includes a fuse unit for repairing a defect. A repair etch refers to a process which includes etching a protection layer and an inter-layer insulation layer formed over a fuse unit to a certain depth to form a fuse box. A semiconductor device also includes a padding unit for electrically coupling an internal circuit and an external circuit so that signals can be input or output. A pad etch refers to a process which includes etching a protection layer formed over a padding unit to a certain depth to expose a portion of the padding unit's surface.

The repair etch and the pad etch are typically performed at substantially the same time. Performing the repair etch and the pad etch at substantially the same time is referred to as a repair/pad etch process. When performing the repair/pad etch process, the repair etch includes etching the protection layer and the inter-layer insulation layer such that a certain thickness of the inter-layer insulation layer remains over the fuse unit.

The pad etch includes etching the protection layer to expose a portion of the padding unit's surface. Thus, an etch target, that is, an etched depth in a fuse region, has a larger value than that in a pad region. Accordingly, the repair/pad etch process is performed using the etch target in the fuse region as the basis of etching.

Consequently, when both the fuse region and the pad region are etched at substantially the same time by the repair/pad etch process, plasma gas often penetrates into the inter-layer insulation layer to damage a bit line formed below the fuse unit or cause disconnection of the bit line.

When the bit line is disconnected, it becomes difficult to measure bit line resistance. In addition, it becomes difficult to setup a process line because a program threshold voltage is abnormally measured. The program threshold voltage is a parameter which monitors key characteristics of a flash memory device. In particular, it becomes difficult to stably monitor electrical characteristics of a memory device because the degree of damage to the bit lines is affected by the fabrication process or characteristics of the device.

In FIGS. 1A to 2B, a typical repair/pad etch process and the related difficulties are examined in detail.

FIGS. 1A and 1B illustrate diagrams of a padding unit in a typical semiconductor device. FIG. 1A illustrates a plan view of the semiconductor device, and FIG. 1B illustrates a cross-sectional view taken along a line I-I′ of the semiconductor device shown in FIG. 1A.

Referring to FIGS. 1A and 1B, bit lines 11, a first padding layer 12 and a second padding layer 13 are formed over a semi-finished substrate 10. An inter-layer insulation layer 14 is formed around the bit lines 11 and the first padding layer 12 and below the second padding layer 13. The second padding layer 13 is formed in a portion of a pad region A. The first padding layer 12 is formed below the second padding layer 13.

Although not illustrated, the first padding layer 12 and the second padding layer 13 are electrically coupled by a contact plug which passes through the inter-layer insulation layer 14.

A protection layer 15 having an opening is formed over the substrate structure including the second padding layer 13. The opening of the protection layer 15 exposes the pad region A. The protection layer 15 is formed by forming a protection material layer over the substrate structure including the second padding layer 13. A portion of the protection material layer formed over the pad region A is selectively etched to form the protection layer 15 having the opening which exposes the pad region A.

As it is described above, the repair/pad etch process is performed using an etch target in a fuse region as the basis of etching. While performing the repair/pad etch process, plasma gas may penetrate through an opening between the second padding layer 13 and the protection layer 15 that exposes portions of the inter-layer insulation layer 14. Such penetration of plasma gas may cause damage or disconnection of the bit lines 11 formed below the exposed portions of the inter-layer insulation layer 14.

FIGS. 2A and 2B illustrate diagrams of a padding unit in a typical semiconductor device. In FIGS. 2A and 2B, a typical method of preventing plasma gas penetration using a second dummy pad and the related difficulties are described. FIG. 2A illustrates a plan view of the semiconductor device, and FIG. 2B illustrates a cross-sectional view taken along a line I-I′ of the semiconductor device shown in FIG. 2A.

Referring to FIGS. 2A and 2B, bit lines 21, a first padding layer 22 and a second padding pattern 23 are formed over a semi-finished substrate 20. The second padding pattern 23 includes a second main pad 23A and a second dummy pad 23B. An inter-layer insulation layer 24 is formed around the bit lines 21 and the first padding layer 22, and below the second padding pattern 23. The first padding layer 22 is formed below the second main pad 23A.

Although not illustrated, the first padding layer 22 and the second padding pattern 23 are electrically coupled by a contact plug which passes through the inter-layer insulation layer 24.

Furthermore, a protection layer 25 having an opening is formed over the substrate structure including the second padding pattern 23. The opening of the protection layer 25 exposes a pad region B. The protection layer 25 is formed by forming a protection material layer over the substrate structure including the second padding pattern 23. A portion of the protection material layer formed over the pad region B is selectively etched to form the protection layer 25 having the opening which exposes the pad region B.

While performing a repair/pad etch process, plasma gas may penetrate into the inter-layer insulation layer 24 through a slit B1 formed between the second main pad 23A and the second dummy pad 23B. Consequently, such penetration of plasma gas may cause damage or disconnection of the bit lines 21 formed below the slit B1.

As the integration scale of a semiconductor device increases, the device response speed should be improved and the bit line capacitance should also be reduced. As such, bit lines are formed of copper instead of the tungsten. However, according to the repair/pad etch process as shown above, bit lines may be damaged or disconnected. In such cases, copper impurity contamination may cause the threshold voltage characteristic, leakage characteristic, and S-slope characteristic of a memory device to change.

Therefore, in order to improve memory device characteristics using bit lines which include copper, a method which can prevent bit line damage during a repair/pad etch process is required.

### SUMMARY OF THE INVENTION

Embodiments of the present invention are directed to a semiconductor device which can prevent damage and disconnection of bit lines during a repair/pad etch process.

In accordance with an aspect of the present invention, a semiconductor device includes: bit lines formed over a substrate; and a padding unit formed over the bit lines. The padding unit includes a first padding layer formed over the bit lines and a second padding layer formed over the first padding layer. A slit is formed in the second padding layer, and the first padding layer is positioned between the slit and the bit lines.

In accordance with another aspect of the present invention, a semiconductor device includes bit lines formed over a substrate, a first padding layer formed over the bit lines, and a second padding layer formed over the first padding layer. The first padding layer includes a first main padding layer and a first dummy padding layer, and a first slit is formed between the first dummy padding layer and the first main padding layer. The second padding layer includes a second main padding layer and a second dummy padding layer, and a second slit is formed between the second dummy padding layer and the second main padding layer. The first padding layer is formed between the second slit and the bit lines, and the second padding layer is formed above the first slit such that the first slit and the second slit are not aligned.

In accordance with another aspect of the present invention, a semiconductor device includes: bit lines formed in a semiconductor substrate; a padding unit including a first padding layer and a second padding layer; and a protection layer formed over the padding unit. The first padding layer is formed over the bit lines and the second padding layer formed over the first padding layer. A first slit is formed in the second padding layer above the first padding layer such that the first padding layer is positioned between the bit lines and the first slit. The protection layer has an opening which exposes the padding unit.

### BRIEF DESCRIPTION OF THE DRAWINGS

FIGS. 1A and 1B illustrate a padding unit of a typical semiconductor device.

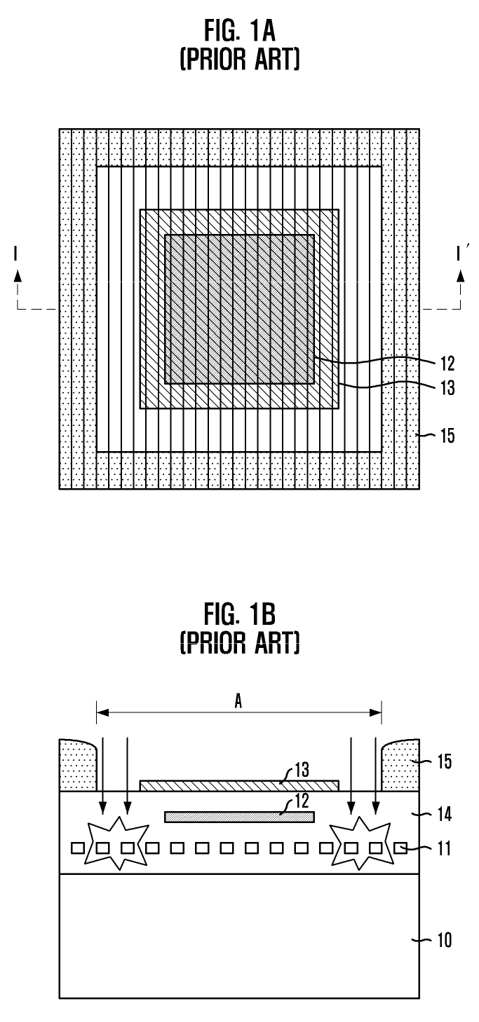

FIGS. 2A and 2B illustrate a padding unit of a typical semiconductor device.

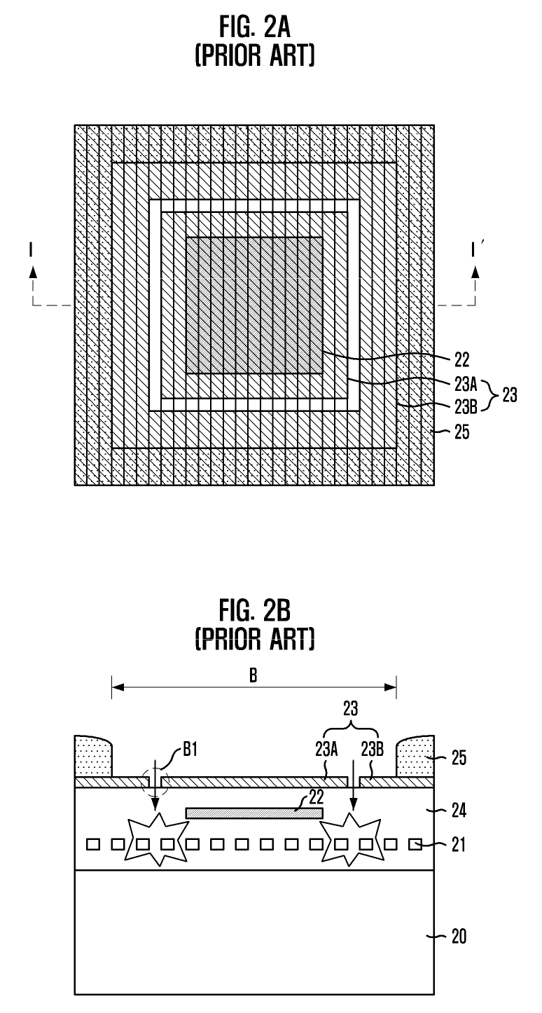

FIGS. 3A and 3B illustrate a padding unit of a semiconductor device in accordance with a first embodiment of the present invention.

FIGS. 4A and 4B illustrate a padding unit of a semiconductor device in accordance with a second embodiment of the present invention.

### DESCRIPTION OF SPECIFIC EMBODIMENTS

Other objects and advantages of the present invention can be understood by the following description, and become apparent with reference to the embodiments of the present invention.

In the figures, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Embodiments of the present invention relate to a semiconductor device. According to the present invention, padding layers are formed above bit lines such that the plasma gas is blocked from damaging the bit lines when the plasma gas penetrates an insulating layer via slits formed between pads in an upper padding layer. In particular, by forming a slit in each padding layer such the slits in different layers are not vertically aligned, damage and disconnection of the bit lines may be prevented when performing a repair/pad etch process. Thus, copper impurity contamination may be prevented even if the bit lines are formed using copper.

Bit lines formed of copper can reduce capacitance between the bit lines by approximately 30% compared to tungsten bit lines. In particular, for a multi-level cell (MLC), read time may be improved by approximately 16% and program time may be improved by approximately 10%. Also, for a 4 bit cell (X4), program time may be improved by approximately 15%.

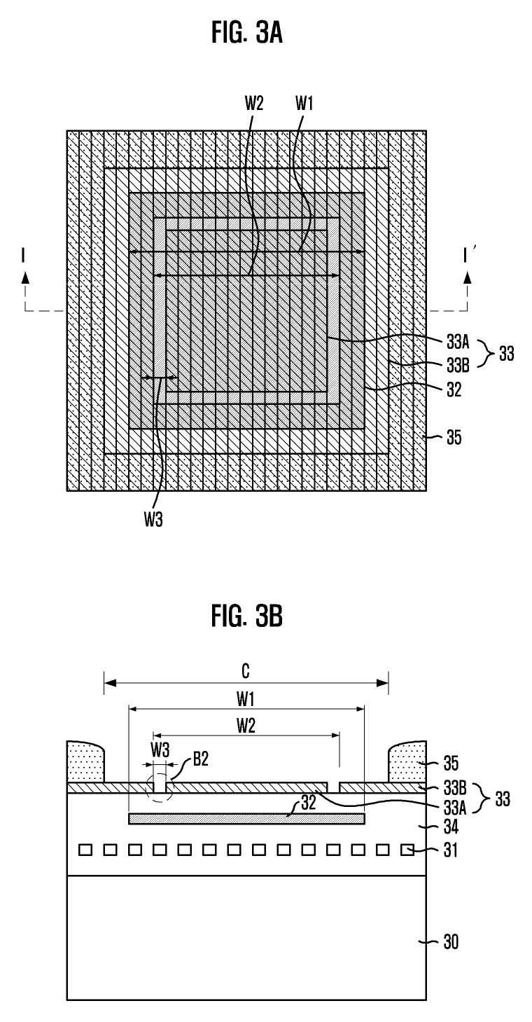

FIGS. 3A and 3B illustrate diagrams showing a padding unit of a semiconductor device in accordance with a first embodiment of the present invention. FIG. 3A illustrates a plan view of the semiconductor device, and FIG. 3B illustrates a cross-sectional view taken along a line I-I′ in a first direction of the semiconductor device shown in FIG. 3A.

Referring to FIGS. 3A and 3B, bit lines 31 are formed over a semi-finished substrate 30. The bit lines 31 may be formed of copper. A padding unit is formed over the bit lines 31. The padding unit may include two or more padding layers. The padding unit includes a first padding layer 32 and a second padding pattern 33. A slit B2 is formed in the second padding pattern 33. The first padding layer 32 is formed between the bit lines 31 and the second padding pattern 33 such that the first padding layer is positioned between the slit B2 and the bit lines 31.

The semiconductor device includes a protection layer 35 having an opening. The protection layer 35 is formed over the substrate structure including the padding unit, and the opening of the protection layer 35 exposes the padding unit. The protection layer 35 is formed by forming a protection material layer over the substrate structure including the padding unit. A portion of the protection material layer formed over a pad region C is selectively etched to form the protection layer 35 having the opening which exposes the pad region C. The protection material layer may be formed by coating polyimide isoindoro-quinazorindione (PIQ), which is a polyimide-based material, and a PIX etch may be performed to form the protection layer 35.

An inter-layer insulation layer 34 is formed around the bit lines 31 and the first padding layer 32, and below the second padding pattern 33. Although not illustrated, the first padding layer 32 and the second padding pattern 33 are electrically coupled by a contact plug which passes through the inter-layer insulation layer 34.

The padding unit may include a main pad and a dummy pad, where the dummy pad is formed a predetermined distance from the main pad. The main pad may be formed such that the main pad covers the pad region C. The dummy pad may be formed such that the dummy pad surrounds the main pad in a ring-like shape. The dummy pad formed in the ring-like shape includes an opening.

FIGS. 3A and 3B illustrate a case where the padding unit includes the first padding layer 32 formed over the bit lines 31 and the second padding pattern 33 formed over the first padding layer 32. In particular, FIGS. 3A and 3B illustrate a case where the second padding pattern 33 includes a second main pad 33A formed over the first padding layer 32 and a second dummy pad 33B formed a predetermined distance from the second main pad 33A.

The slit B2 is formed between the second main pad 33A and the second dummy pad 33B such that the first padding layer 32 is formed between the slit B2 and the bit lines 31. Thus, at least one of the first padding layer 32 and the second padding pattern 33 is formed in the pad region C over the bit lines 31. As a result, even if plasma gas penetrates into the inter-layer insulation layer 34 through the slit B2 formed between the second main pad 33A and the second dummy pad 33B while performing a repair/pad etch process, the penetration of the plasma gas can be blocked by the first padding layer 32 formed below the slit B2. That is, damage to the bit lines 31 by plasma gas may be prevented.

The width of the first padding layer 32, as represented by reference denotation W1, may be larger than the width of an opening of the second dummy pad 33B, as represented by reference denotation W2. Also, the width of the slit B2, as represented by reference denotation W3, may range from approximately 0.5 μm to approximately 1.5 μm.

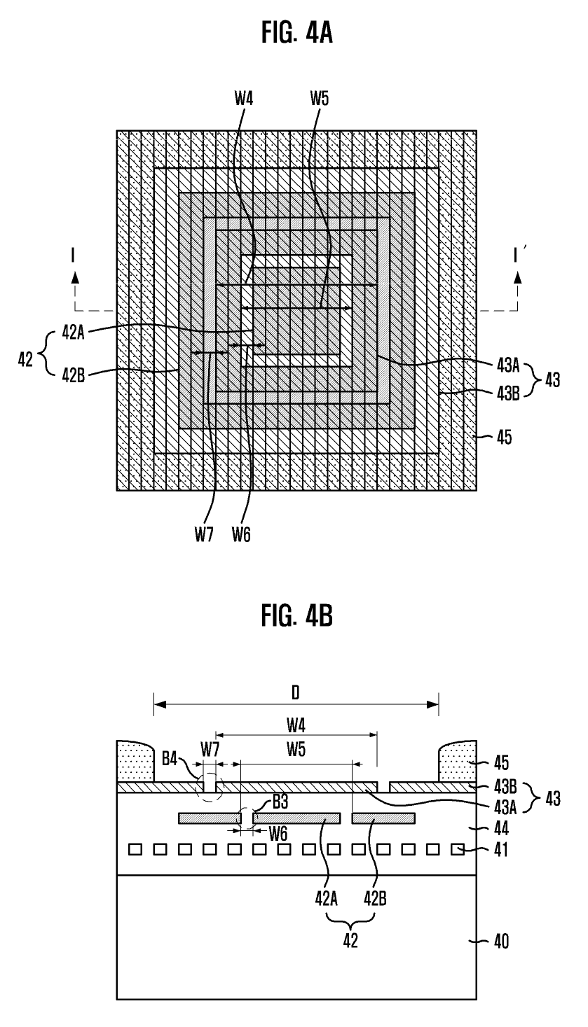

FIGS. 4A and 4B illustrate diagrams showing a padding unit of a semiconductor device in accordance with a second embodiment of the present invention. FIG. 4A illustrates a plan view of the semiconductor device, and FIG. 4B illustrates a cross-sectional view taken along a line I-I′ in a first direction of the semiconductor device shown in FIG. 4A.

Referring to FIGS. 4A and 4B, bit lines 41 are formed over a semi-finished substrate 40. A padding unit is formed over the bit lines 41. The padding unit includes two or more padding layers. The padding unit includes a first padding pattern 42 and a second padding pattern 43. The padding unit is formed such that a first slit B3 is formed in the first padding pattern 42 and a second slit B4 is formed in the second padding pattern 43. The first slit B3 and the second slit B4 are not aligned such that at least one of the first padding pattern 42 and the second padding pattern 43 is formed above each of the bit lines 41. That is, the second padding pattern 43 is formed above the first slit B3, and the first padding pattern 42 is formed below the second slit B4.

The semiconductor device includes a protection layer 45 having an opening. The protection layer 45 is formed over the substrate structure including the padding unit, and the opening of the protection layer 45 exposes the padding unit. The protection layer 45 is formed by forming a protection material layer over the substrate structure including the padding unit. A portion of the protection material layer formed over a pad region D is selectively etched to form the protection layer 45 having the opening which exposes the pad region D. The protection material layer may be formed by coating polyimide isoindoro-quinazorindione (PIQ), which is a polyimide-based material, and a PIX etch may be performed to form the protection layer 45.

An inter-layer insulation layer 44 is formed around the bit lines 41 and the first padding pattern 42, and below the second padding pattern 43. Although not illustrated, the first padding pattern 42 and the second padding pattern 43 are electrically coupled by a contact plug which passes through the inter-layer insulation layer 44.

The padding unit may include main pads and dummy pads, where the dummy pads are formed a predetermined distance from the main pads. The dummy pads may be formed such that the dummy pads surround the main pads in a ring-like shape. In this case, the dummy pads formed in the ring-like shape include an opening. In particular, the padding unit may be formed such that the first slit B3 and the second slit B4 are not aligned.

FIGS. 4A and 4B illustrate a case where the padding unit includes the first padding pattern 42 is formed above the bit lines 41 and the second padding pattern 43 is formed above the first padding pattern 42. In this case, the first padding pattern 42 includes a first main pad 42A and a first dummy pad 42B formed a predetermined distance from the first main pad 42A, and the second padding pattern 43 includes a second main pad 43A and a second dummy pad 43B formed a predetermined distance from the second main pad 43A.

The first slit B3 is formed between the first main pad 42A and the first dummy pad 42B, and the second slit B4 is formed between the second main pad 43A and the second dummy pad 43B. The padding unit is formed such that the first slit B3 and the second slit B4 are not vertically aligned.

The bit lines are not directly exposed to the pad region D because the second main pad 43A is formed above the first slit B3, and the first dummy pad 42B is formed between the second slit B4 and the bit lines 41. Thus, even if plasma gas penetrates into the inter-layer insulation layer 44 through the second slit B4 formed between the second main pad 43A and the second dummy pad 43B while performing a repair/pad etch process, the first dummy pad 42B formed below the second slit B4 blocks the plasma gas from penetration toward the bit lines 41. That is, damage to the bit lines 41 by plasma gas may be prevented.

The width of the second main pad 43A, as represented by reference denotation W4, may be larger than the width of an opening of the first dummy pad 42B, as represented by reference denotation W5. Also, the width of the first slit B3, as represented by reference denotation W6, may be substantially the same as or larger than the width of the second slit B4, as represented by reference denotation W7. The widths W6 and W7 of the first slit B3 and the second slit B4, respectively, may range from approximately 0.5 μm to approximately 1.5 μm.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
bit lines formed over a substrate; and
a padding unit formed over the bit lines, wherein the padding unit comprises a first padding layer formed over the bit lines and a second padding layer formed over the first padding layer, a slit being formed in the second padding layer,
wherein the first padding layer is positioned between the slit and the bit lines.

2. The semiconductor device of claim 1, wherein the second padding layer comprises:
a main padding layer; and
a dummy padding layer formed a predetermined distance from the main padding layer.

3. The semiconductor device of claim 2, wherein the slit is formed between the main padding layer and the dummy padding layer.

4. The semiconductor device of claim 2, wherein the dummy padding layer is formed in a ring-like shape surrounding the main padding layer.

5. The semiconductor device of claim 4, wherein the width of the first padding layer is larger than the width of an opening of the second dummy padding layer.

6. The semiconductor device of claim 1, wherein the bit lines comprise copper.

7. A semiconductor device comprising:
bit lines formed over a substrate;
a first padding layer formed over the bit lines, wherein the first padding layer comprises a first main padding layer and a first dummy padding layer, a first slit being formed between the first dummy padding layer and the first main padding layer; and
a second padding layer formed over the first padding layer, wherein the second padding layer comprises a second main padding layer and a second dummy padding layer, a second slit being formed between the second dummy padding layer and the second main padding layer,
wherein the first padding layer is formed between the second slit and the bit lines and the second padding layer is formed above the first slit such that the first slit and the second slit are not aligned.

8. The semiconductor device of claim 7, wherein the width of the second main padding layer is larger than the width of an opening of the first dummy padding layer.

9. The semiconductor device of claim 7, wherein the width of the first slit is substantially the same or larger than the width of the second slit.

10. The semiconductor device of claim 7, wherein the bit lines comprise copper.

11. A semiconductor device, comprising:
bit lines formed in a semiconductor substrate;
a padding unit comprising a first padding layer formed over the bit lines and a second padding layer formed over the first padding layer, wherein a first slit is formed in the second padding layer above the first padding layer such that the first padding layer is positioned between the bit lines and the first slit; and
a protection layer formed over the padding unit, wherein the protection layer has an opening which exposes the padding unit.

12. The semiconductor device of claim 11, wherein the second padding layer comprises:
a second main padding layer and a second dummy padding layer, wherein the first slit is formed between the second main padding layer and the second dummy padding layer.

13. The semiconductor device of claim 12, wherein the width of the first padding layer is larger than the width of an opening of the second dummy padding layer.

14. The semiconductor device of claim 11, wherein the first padding layer comprises:
a first main padding layer and a first dummy padding layer wherein a second slit is formed between the first main padding layer and the first dummy padding layer, the first slit not being in alignment with the second slit.

15. The semiconductor device of claim 14, wherein the width of the second main padding layer is larger than the width of an opening of the first dummy padding layer.

16. The semiconductor device of claim 11, wherein the bit lines comprise copper.
